(19) United States
(12) Patent Application Publication
(10) Pub. No.: US 2008/0024347 A1
(43) Pub. Date: Jan. 31, 2008

(54) High-resolution broadband ADC

(75) Inventor: Myung-Jun Choe, Thousand Oaks, CA (US)

Correspondence Address: KOPPEL, PATRICK & HEYBL, 555 ST. CHARLES DRIVE, SUITE 107, THOUSANDS OAKS, CA, 91360, US

(73) Assignee: ROCKWELL SCIENTIFIC LICENSING, LLC

(21) Appl. No.: 11/494,866

(22) Filed: Jul. 28, 2006

(51) Int. Cl. H03M 1/12

(52) U.S. Cl. 341/155

(57) ABSTRACT

An analog-to-digital converter (ADC) uses a combination of sampling circuits and ADCs to convert the signal from analog to digital. By sampling an analog signal with a single front-end sampling circuit, the ADC substantially eliminates the dynamic error that is normally associated with mismatched parallel sampling circuits. The clean signal is then sampled a second time. Several sampling circuits arranged in parallel can be used to increase the bandwidth of the circuit. After the analog signal is sampled it is then converted to a time-interleaved digital signal. The ADC is able to achieve high-resolution broadband signal conversion while consuming much less power than other high-performance ADCs in systems such as GaAs and InP.

### BACKGROUND OF THE INVENTION

1. Field of the Invention

This invention relates to analog-to-digital converters, and more particularly to analog to digital converters capable of high resolution conversion performed at relatively high speeds.

2. Description of the Related Art

Analog-to-digital converters (ADCs) and their counterpart digital-to-analog converters (DACs) are an important class of electrical systems. They are ubiquitous in electrical circuits, having applications ranging from automotive systems to advanced communication systems. Just as the name conveys, ADCs accept a continuous analog signal and convert it to a discrete digital signal. DACs perform the reverse operation. A good ADC recreates an analog signal digitally while maintaining the integrity of the original signal and limiting information loss to an acceptable level.

Several different design approaches have been utilized to realize ADC circuitry, such as flash converters, single- and dual-slope integrating converters, and tracking converters. Each of these designs offers various advantages over the others. Some important characteristics of ADCs include resolution, conversion rate or speed, and step recovery. Resolution is the number of binary bits output by the converter. Speed is a measure of how fast the converter can output a new binary number. In discrete time systems and digital signal processing, bandwidth is associated with the sampling rate, and the term is often used to describe the speed of such a system. Step recovery is a measure of how fast a converter can react in response to a large, sudden jump in the input signal.

A flash converter is formed as a series of comparators, each having an associated reference voltage. The input signal is continually compared to the series of increasing reference voltages. For any given input voltage, a corresponding set of comparators will output a signal which is then fed into a priority encoder circuit which produces a binary output. Flash converters usually operate at high speeds (high bandwidth) with good step recovery but have relatively poor resolution.

Single- and dual-slope ADCs use an op-amp circuit configured as an integrator to generate a saw-tooth waveform which serves as the reference signal. The amount of time that it takes the reference signal to exceed the input signal is measured by a precisely clocked digital counter. Integrating converters have good resolution but are generally slower than other designs.

A third type of ADC is the tracking variety. The tracking converter uses a DAC and an up/down counter to generate the digital signal. The counter is continuously clocked and feeds its output into the DAC. The analog output of the DAC is then fed back and compared to the input signal using a comparator. The comparator provides the high/low signal necessary to cause the counter to operate in “count up” or “count down” mode, allowing the counter to track the input signal in discrete steps. Tracking ADCs have acceptable resolution and high bandwidths but suffer from poor step recovery.

A great deal of research and design work has been done to achieve a high-bandwidth, high-resolution ADC. This is problematic as these two characteristics are inversely related. A high-resolution output requires large amounts of data to be processed, increasing system process time and thus decreasing bandwidth. Advances in the area of high-bandwidth, high-resolution ADCs have been made in some systems such as GaAs and InP; however, these systems require a great deal more power than do systems using silicon, for example.

The benefits of using multiple groups of track-and-hold (T/H) type circuits and a plurality of ADCs to achieve a high-resolution broadband converter has been discussed in several articles. In one, the authors suggest using multiple front-end ADCs to sample the signal prior to conversion. [See Poulton et al., A 4 GSample/s 8 b ADC in 0.35 um CMOS, International Solid-State Circuits Conference, Session 10: High-Speed ADCs, Paper 10.1, February 2002]. Another article discusses using a buffer to enable the signal to drive multiple front-end T/H circuits before converting the signal to the digital regime. [See Poulton et al., A 20 GS/s 8 b ADC with a 1 MB Memory in 0.18 μm CMOS, International Solid-State Circuits Conference, Session 18: Nyquist A/D Converters, Paper 18.1, February 2003]. Another article discusses using multiple ADCs to achieve high speed conversion. This paper details the complexity associated with correcting dynamic errors resulting from the mismatch of multiple ADCs with separate samplers for each ADC, using digital signal processing on the back end. [See Seo et al., Comprehensive Digital Correction of Mismatch Errors for a 400-Msamples/s 80-dB SFDR Time-Interleaved Analog-to-Digital Converter, IEEE Transactions on Microwave Theory and Techniques, Vol. 53, No. 3, March 2005).

### SUMMARY OF THE INVENTION

Briefly, and in general terms, the invention is directed to an analog-to-digital converter (ADC) that provides a digital output signal in response to an analog input signal, comprising a front-end track-and-hold (T/H) sampling circuit, accepting an input signal and generating a static sampled signal; a plurality of ADCs arranged in parallel, each of the ADCs receiving the static sampled signal, the plurality of ADCs outputting interleaved digital signals; and a timing circuit.

In another aspect, the invention relates to an ADC that provides a digital output signal in response to an analog input signal, comprising a front-end track-and-hold (T/H) sampling circuit, accepting an input signal and generating an intermediate sampled signal; a plurality of T/H decimating sampling circuits arranged in parallel, each of the decimating sampling circuits receiving an intermediate sampled signal and generating a final sampled signal; a plurality of ADCs arranged in parallel, each of the ADCs receiving the final sampled signal and outputting an interleaved digital signal; and a timing circuit.

In another aspect, the invention relates to a control system comprising an analog input signal; a timing circuit; a first-tier sampling circuit; a plurality of second-tier sampling circuits driven by the first-tier sampling circuit; a plurality of analog-to-digital converters (ADCs) driven by the second-tier sampling circuits, the plurality of ADCs outputting interleaved digital signals; a processor accepting signals from said plurality of ADCs; and a load circuit controlled by said processor.

In another aspect of the invention, the invention relates to a method for converting an analog signal to a digital signal comprising inputting an analog signal; sampling the analog signal with a wide-band sampling circuit to produce a static sampled signal; quantizing the sampled signal with a plurality of high-resolution, low-speed analog-to-digital converters (ADCs) to produce a quantized interleaved signal; and outputting at least one digital signal.

### BRIEF DESCRIPTION OF THE DRAWINGS

FIG. 1 is a flow diagram of an analog-to-digital converter (ADC) with a single front-end sampling circuit.

FIG. 2 is a flow diagram of an ADC with a two-tiered sampling circuit architecture.

FIG. 3 is a flow diagram of the back-end of an ADC connected to a serializer circuit.

FIG. 4 is a flow diagram of a control system making use of an ADC with a two-tiered sampling architecture and a processor to control a load circuit.

FIG. 5 is a flow chart illustrating a method for converting an analog signal to a digital signal.

### DETAILED DESCRIPTION OF THE INVENTION

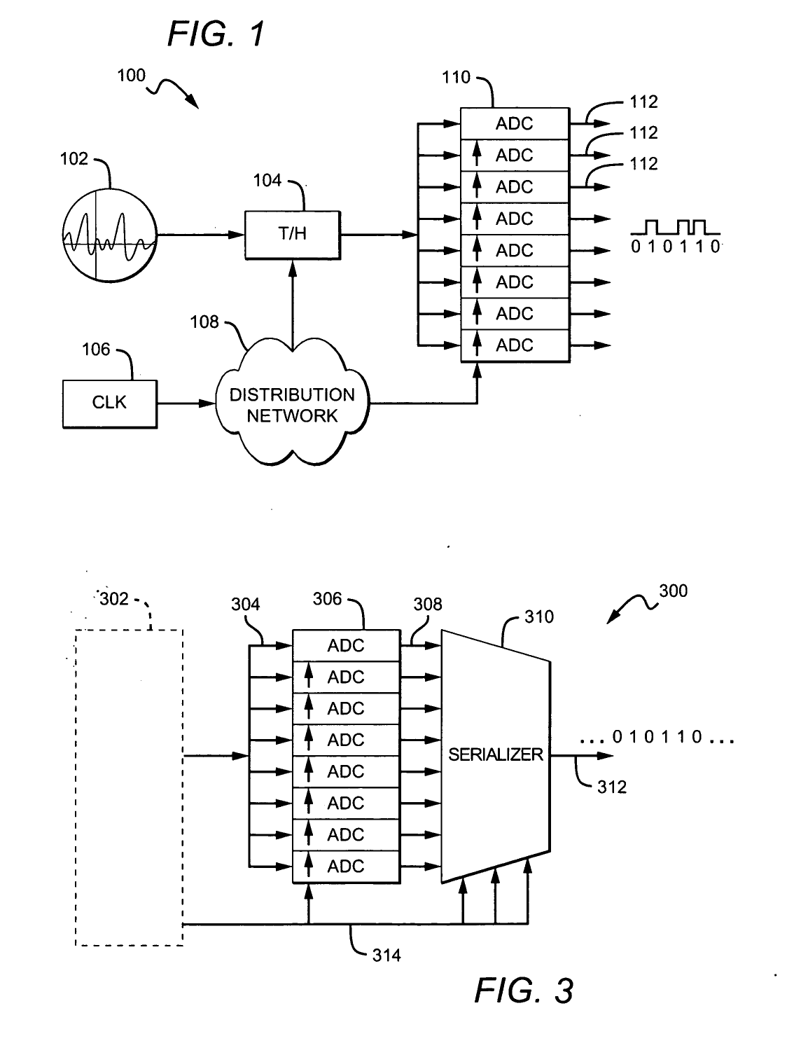

FIG. 1 shows one embodiment of an ADC 100 according to the present invention. ADC 100 has analog signal 102 as its input which could come from any electrical system that has an analog output, such as, for example, an audio/video source, a thermocouple, or a photodiode. Analog signal 102 is input to front-end sampling circuit 104. Various different sampling circuits may be used, for example, track-and-hold (T/H) circuits or sample-and-hold (S/H) circuits. These circuits are necessary to hold the signal constant during the analog-to-digital conversion process. Front-end sampling circuit 104 is preferably a high-performance, wide-band (i.e., bandwidth >100 MHz) T/H as shown in FIG. 1. Sampling circuit 104 is driven by clock 106 which is preferably a low-jitter (i.e., max jitter <10 ps), precision clock driver. Clock 106 is connected to sampling circuit 104 via clock distribution network 108.

Signal 102 is sampled at an interval sufficient to preserve the integrity of the signal. The sampling rate should always exceed twice the bandwidth of the input signal. This ensures that the signal can be accurately recreated from the digital data. If the sampling rate is too slow, the digital data may show a signal with a much smaller frequency. This is known as aliasing and can be very problematic when recreating the original signal. Therefore, it is important to sample at a rate higher than twice the input bandwidth.

By sampling signal 102 at the front end, any error associated with dynamic mismatch of sampling circuits is removed, resulting in a static sampled signal which can then be fed into a plurality of ADCs 110. The timing signal from clock 106 is fed via clock distribution network 108 into each converter within ADCs 110. Each ADC converts a small segment of the sampled signal into a digital output. For example, the first ADC converts a segment of the sampled signal responding to a clock pulse. Then, the second ADC converts the next segment of the sampled signal in response to a clock pulse. This process continues until each ADC has converted a segment of the sampled signal, and then the process begins again with the first ADC.

The result is a digital output where each ADC is outputting a signal that is representative of the input signal over a specific time period of that signal. Such an output is known in the art as time-interleaved signals. FIG. 1 shows interleaved digital signals 112 as output from the plurality of ADCs 110. These signals can then be processed and/or put into serial form. The process of serializing the interleaved digital signals 112 is discussed below and illustrated in FIG. 3.

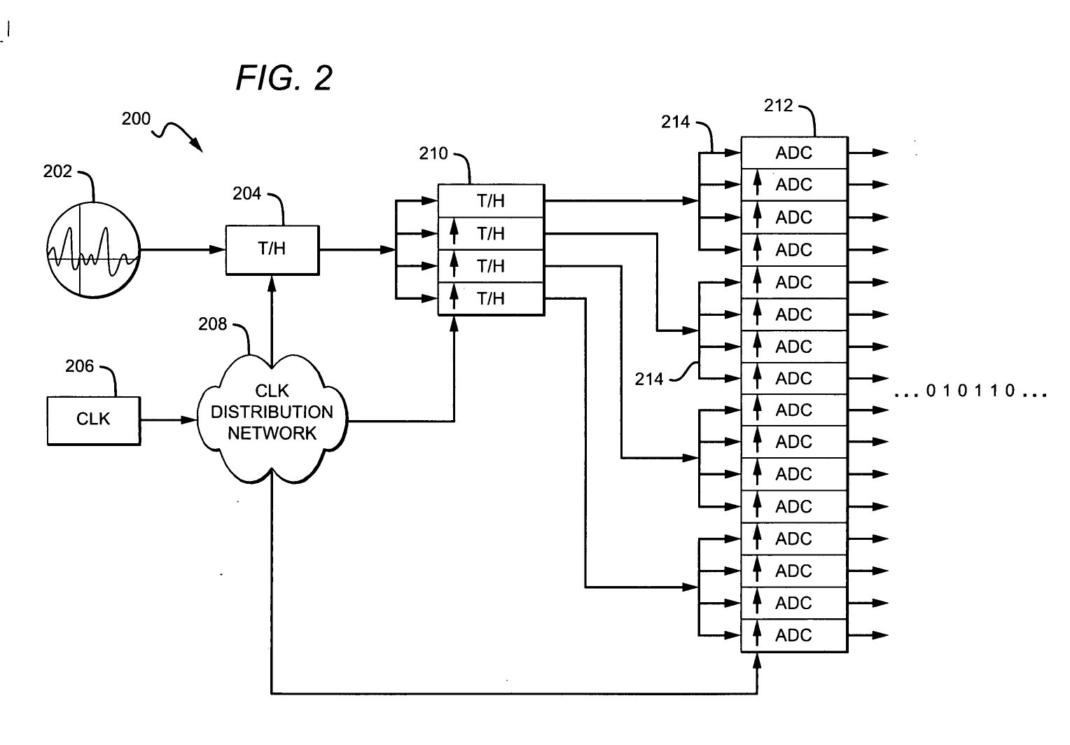

FIG. 2 shows another embodiment of an ADC 200 according to the present invention. ADC 200 shares a similar structure with the embodiment shown in FIG. 1, except that ADC 200 employs a two-tier sampling architecture. Analog signal 202 is input into a first-tier, front-end sampling circuit 204 as shown in FIG. 2. Sampling circuit 204 is connected to clock circuit 206 via clock distribution network 208. Sampling circuit 204 samples analog signal 202 and outputs an intermediate sampled signal which can then be regarded as a static signal.

The sampled signal is then distributed to a second tier of decimating sampling circuits 210. Sampling circuits 210 are arranged in parallel such that the combination of front-end sampling circuit 204 and decimating sampling circuits 210 functions as a sample-and-hold (S/H) system. The parallel arrangement of decimating sampling circuits 210 allows for interleaving of the sampled signals prior to their conversion into digital form, permitting the system to perform the conversion operation more quickly without sacrificing resolution.

Normally the parallel arrangement of the decimating sampling circuits would be problematic as it would introduce dynamic error into the system due to the mismatch of the different sampling circuits. This dynamic error would then have to be corrected using additional digital signal processing (DSP) circuitry which adds complexity and cost to the system. However, because front-end sampling circuit 204 outputs a signal which can be regarded as static, the dynamic mismatch is effectively eliminated. Thus, the system must only compensate for any static error present in the sampling circuits. This is beneficial because static errors, non-linearities that are amplitude dependent, are relatively easy to correct using real-time or post-acquisition processing; whereas frequency-dependent dynamic errors are much more difficult and expensive to correct.

Decimating sampling circuits 210 output an interleaved sampled signal. This signal is fed into a plurality of ADCs 212 with each ADC connected to clock circuit 206 via the clock distribution network 208. ADCs 212 are arranged in groups 214 to handle all of the interleaved sampled signals from decimating sampling circuits 210. Similarly as discussed above, each ADC group 214 converts the output of one of the decimating sampling circuits 210 to an interleaved digital signal. This signal can then be converted to one or more serial digital signals.

FIG. 3 shows another embodiment of an ADC 300 according to the present invention. Sampling component 302 can include any of the sampling schemes discussed with respect the previous embodiments of the invention. Sampling component 302 outputs sampled signal 304 which is fed into ADCs 306 as shown. Each ADC of ADCs 306 converts a segment of sampled signal 304 into a digital signal. Thus, ADCs 306 output interleaved digital signals 308 which are input to serializer circuit 310. Serializer circuit 310 recombines the interleaved digital signal using any of various techniques that are well-known in the art into at least one serial digital signal 312.

Each ADC receives clock signal 314 from clock distribution network (shown in FIGS. 1, 2). Clock signal 314 is also fed into serializer circuit 310. Serializer circuit 314 requires a clock line for each bit of resolution that the circuit is required to handle. FIG. 3 shows serializer circuit 310 capable of handling serialization of eight interleaved digital signals 308 into one signal using a 3-bit control signal.

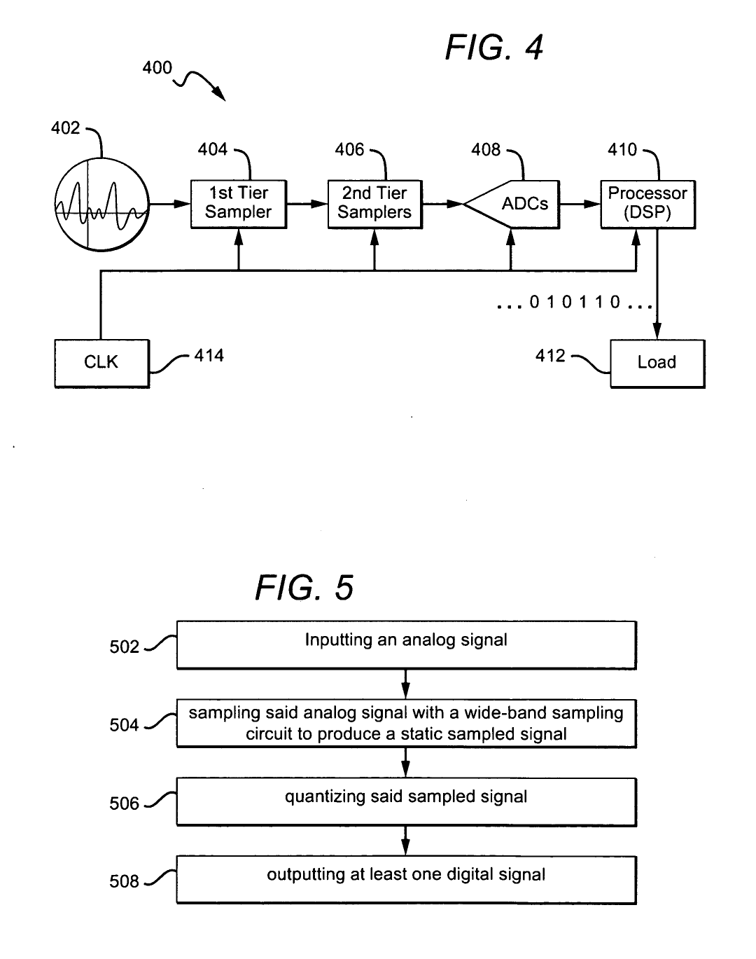

FIG. 4 shows a control circuit 400 according to the present invention. Analog signal 402 is input to first-tier sampling circuit 404. First-tier sampling circuit 404 samples the signal, outputting a signal which can be regarded as static. The static sampled signal is then fed into second-tier sampling circuits 406. These circuits 406 sample a segment of the input signal and output interleaved sampled signals. ADCs 408 convert the sampled signals from analog to digital interleaved signals. The interleaved digital signals can then be recombined into one or more serial digital signals using a serializer circuit (not shown) or by digital signal processing means (as shown in FIG. 4). Here, the digital signal enters into processor 410 where it can undergo digital manipulation to put it into a form necessary to control load circuit 412.

Circuit components 404, 406, 408 and 410 are all synchronized with timing circuit 414. Timing circuit 414 should include a precision low-jitter clock and any necessary circuitry to distribute the signal to the components.

FIG. 5 represents a method for converting an analog signal to a digital signal according to the present invention. An analog signal is provided as input to the system as shown in 502. The input signal is sampled by a wide-band sampling circuit (i.e., bandwidth exceeding 100 MHz). The sampling circuit outputs a sampled signal which can be regarded as static as shown in 504. The static sampled signal can then be input directly into the ADCs, or it can be fed into a secondary set of sampling circuits, using a two-tier sampling design. The first sampling circuit eliminates any dynamic error that would normally be associated with a parallel arrangement of sampling circuits. The secondary set of sampling circuits outputs interleaved sampled signals.

Whether a single-tier or a two-tier sampling design is used, a sampled signal is input into a plurality of high-resolution, low-speed (i.e., clock speed less than 100 MHz) ADCs for quantization. Each individual ADC converts a portion of the sampled signal with the plurality of ADCs outputting a quantized interleaved signal as shown in 506. The signal can then be serialized into a serial digital signal or output as interleaved digital signals as shown in 508.

Although the present invention has been described in detail with reference to certain preferred configurations thereof, other versions are possible. For example, the ADC systems described above can be constructed using any number of sampling circuits and individual ADCs as necessitated by the design. The ADC systems described above are only examples of the many different embodiments of ADC systems according to the present invention. Other modifications can be made without departing from the spirit and scope of the invention.

We claim:

1. An analog-to-digital converter (ADC) that provides a digital output signal in response to an analog input signal, comprising:
a front-end sampling circuit connected to accept said input signal and generate a static sampled signal; and
a plurality of ADCs arranged in parallel, each of said ADCs connected to receive said static sampled signal, said plurality of ADCs outputting interleaved digital signals.

2. The ADC of claim 1, wherein said front-end sampling circuit comprises a track-and-hold (T/H) sampler.

3. The ADC of claim 1, further comprising:
a serializer circuit connected to convert said interleaved digital signals to at least one serial digital signal.

4. The ADC of claim 1, wherein said plurality of ADCs comprises low-power silicon pipelined ADCs.

5. The ADC of claim 1, further comprising:
a timing circuit connected to provide a clock signal to the components of said ADC.

6. The ADC of claim 5, said timing circuit further comprising:
a low-jitter clock driver connected to provide said clock signal; and
a clock distribution circuit connected to distribute said clock signal to said components of said ADC.

7. An analog-to-digital converter (ADC) that provides a digital output signal in response to an analog input signal, comprising:
a front-end sampling circuit, connected to accept said input signal and generate an intermediate sampled signal;
a plurality of decimating sampling circuits arranged in parallel, each of said decimating sampling circuits connected to receive said intermediate sampled signal and generate a final sampled signal; and
a plurality of ADCs arranged in parallel, each of said ADCs receiving said final sampled signal and outputting an interleaved digital signal.

8. The ADC of claim 7, wherein said front-end sampling circuit comprises a track-and-hold (T/H) sampler circuit.

9. The ADC of claim 7, wherein said decimating sampling circuits comprise track-and-hold (T/H) sampler circuits.

10. The ADC of claim 7, further comprising:
a timing circuit connected to provide a clock signal to said ADC.

11. The ADC of claim 7, further comprising:
a serializer circuit, converting said interleaved digital signal to at least one serial digital signal.

12. The ADC of claim 7, wherein said decimating sampling circuits sample said intermediate sampled signal in an ordered sequence with a substantially uniform delay between samples.

13. A control system, comprising:
an analog input signal;
a timing circuit connected to provide a clock signal to said control system;
a first-tier sampling circuit connected to accept said analog input signal;
a plurality of second-tier sampling circuits driven by said first-tier sampling circuit;
a plurality of analog-to-digital converters (ADCs) driven by said second-tier sampling circuits, said plurality of ADCs connected to output interleaved digital signals;
a processor connected to accept signals from said plurality of ADCs; and
a load circuit controlled by said processor.

14. The control system of claim 13, further comprising:
a serializer circuit connected to accept a plurality of interleaved digital signals from said second-tier sampling circuits, and outputting to said processor at least one serial digital signal.

15. The control system of claim 13, wherein said first-tier sampling circuit comprises a wide-band track-and-hold (T/H) circuit.

16. The control system of claim 13, wherein said second-tier sampling circuits are T/H circuits.

17. The control system of claim 13, wherein said ADCs are high-resolution, low-speed ADCs.

18. The control system of claim 13, said timing circuit further comprising:
a low-jitter clock driver; and
a clock distribution network.

19. The control system of claim 13, wherein said plurality of second-tier sampling circuits samples a signal from said first-tier sampling circuit in an ordered sequence with a substantially uniform delay between samples.

20. A method for converting an analog signal to a digital signal, comprising:
inputting an analog signal;
sampling said analog signal to produce a static sampled signal;
quantizing said sampled signal to produce a quantized interleaved signal; and
outputting at least one digital signal.

21. The method of claim 20, wherein said analog signal is sampled with wide-band sampling circuit.

22. The method of claim 20, wherein said static sampled signal is input to a set of sampling circuits, each of said sampling circuits outputting a sampled portion of the static sampled signal.

23. The method of claim 22, wherein said sampling circuits are track-and-hold (T/H) circuits.

24. The method of claim 20, wherein said quantized interleaved signal is serialized such that said at least one digital signal is a serial digital signal.

25. The method of claim 20, wherein said ADCs are low-power silicon pipelined ADCS.

26. An analog-to-digital converter, comprising:
at least one first-tier sampling circuit;
at least one second-tier sampling circuit connected with said at least one first-tier sampling circuit to output a sampled signal;
wherein said first- and second-tier sampling circuits are connected such that the dynamic error is substantially eliminated from said sampled signal.
